(19) United States
(12) Patent Application Publication
(10) Pub. No.: US 2013/0026212 A1
(43) Pub. Date: Jan. 31, 2013

(54) SOLDER DEPOSITION SYSTEM AND METHOD FOR METAL BUMPS

(71) Applicants: Samuel Waising Tam, Daly City, CA (US); Bryan Sik Pong Lee, Selangor (MY); Tak Shing Pang, New Territories (HK)

(72) Inventors: Samuel Waising Tam, Daly City, CA (US); Bryan Sik Pong Lee, Selangor (MY); Tak Shing Pang, New Territories (HK)

(73) Assignee: FLEXTRONICS AP, LLC, Broomfield, CO (US)

(21) Appl. No.: 13/543,576

(22) Filed: Jul. 6, 2012

Related U.S. Application Data
(60) Provisional application No. 61/504,797, filed on Jul. 6, 2011.

(51) Int. Cl. H05K 13/04

(52) U.S. Cl. 228/175; 228/256; 228/180.1

(57) ABSTRACT

A manufacturing technique includes creating stud bumps on the electrical contacts on a die, either in wafer or die form. A separate stencil or carrier is provided with cavities that correspond to the electrical contacts on the die. The cavities are filled with solder paste and the die is brought into close proximity with the stencil so that the stud bumps extend into the cavities and come into contact with the solder paste. When the die is removed, the solder paste stays affixed to the stud bumps and thereby the solder paste is transferred and delivered to the stud bumps. The die can then be affixed to a substrate such as a PCB.

### CROSS REFERENCE

This application is the non-provisional of U.S. Provisional Pat. App. No. 61/504,797 filed Jul. 6, 2011, entitled “Solder Deposition System and Method for Metal Bumps,” which is hereby incorporated by reference into this application.

### BACKGROUND

The disclosure herein relates generally to electronic devices, and more particularly to techniques for attaching electronic components. Even more particularly, it relates to a manufacturing design that reduces costs and increases manufacturing throughput.

Solder is often used to connect the electrical contacts of one electrical component with another electronic component. There are various methods that have been used to apply the solder. It should be borne in mind that as electronic components get smaller and smaller and their functionality and capabilities have increased, the pitch between adjacent electrical contacts on the components have shrunk. This has greatly added to the challenge of applying solder and connecting the components. One method has included depositing photo resist on a component, electroplating a copper pillar onto each metal pad on the components (in the areas not covered by the photo resist), and then printing and re-flowing a solder cap onto the copper pillar, followed by removing the photo resist. This method suffers from high costs for sputtering, lithography, and plating.

Another method has included creating stud bumps on the metal pads of the component, placing solder paste directly onto each of the metal pads on the other component, and then placing the stud bump against the solder paste on the other component and reflowing the solder. This method has suffered from a constraint as to the amount of solder that can be applied to each small metal pad on the other component and from the inability to easily electrically test the component after the stud bumps have been applied (due to the irregular shape of the stud bumps).

What is needed, therefore, is a manufacturing design that is less expensive and has a higher throughput.

### SUMMARY

Disclosed herein is a method for applying solder to stud bumps on a die, including: providing a die with a plurality of stud bumps, each stud bump affixed to a corresponding metal pad on the die; providing a stencil with a plurality of cavities corresponding to the relative positions of the stud bumps on the die; placing solder paste into the cavities of the stencil; dipping the stud bumps into the cavities of the stencil so as to cause the solder paste to come into contact with the stud bumps; and removing the stud bumps from the cavities so that the solder paste is affixed to the stud bumps.

The method may further include wiping away excess solder paste from the stencil in the areas outside of the cavities. The die may have been created from a wafer of a plurality of die. A plurality of the die may be connected together as part of a wafer and the stencil has cavities for all of the stud bumps on all of the die on the wafer. The solder paste may have been heated to elevate the temperature thereof to facilitate the solder in the solder paste affixing to the stud bumps. The method may further include cooling down the solder after it has been affixed to the stud bumps and prior to removing the stud bumps from the cavities.

The stud bumps on the die may include copper. The solder may be placed into the cavities by printing. The method may further include providing a substrate with metal contacts corresponding to the stud bumps on the die; and affixing the stud bumps to the metal contacts on the substrate with the solder. The method may further include reflowing the solder. The method may further include adding an adhesive material between the die and the substrate to further affix the die and substrate together. The adhesive material may include underfill. The adhesive material may be dispensed after the die has been affixed to the substrate with the solder. The adhesive material may be dispensed before the die has been affixed to the substrate with the solder. The adhesive material may also include flux. The underfill may be dispensed in a pattern across the substrate. The adhesive material may include non-conductive paste (NCP). The NCP may be dispensed in a pattern across the substrate. The method may further include curing the adhesive. All of the stud bumps may be dipped into the cavities simultaneously.

### BRIEF DESCRIPTION OF THE DRAWINGS

The disclosure herein is described with reference to the following drawings, wherein like reference numbers denote substantially similar elements:

FIG. 1 is a process flow for applying solder to stud bumps on an electronic component;

FIGS. 2a, 2b, 2c, and 2d are further details on a process flow for applying solder to stud bumps on an electronic component;

FIG. 3 is a process flow for wafer processing;

FIG. 4 is another embodiment of a process flow for wafer processing; and

FIG. 5 is another embodiment of a process flow for wafer processing.

### DETAILED DESCRIPTION

While the embodiments disclosed herein are susceptible to various modifications and alternative forms, specific embodiments thereof have been shown by way of example in the drawings and are herein described in detail. It should be understood, however, that it is not intended to limit the invention to the particular form disclosed, but rather, the invention is to cover all modifications, equivalents, and alternatives of embodiments of the invention as defined by the claims. The disclosure is described with reference to the drawings, wherein like reference numbers denote substantially similar elements.

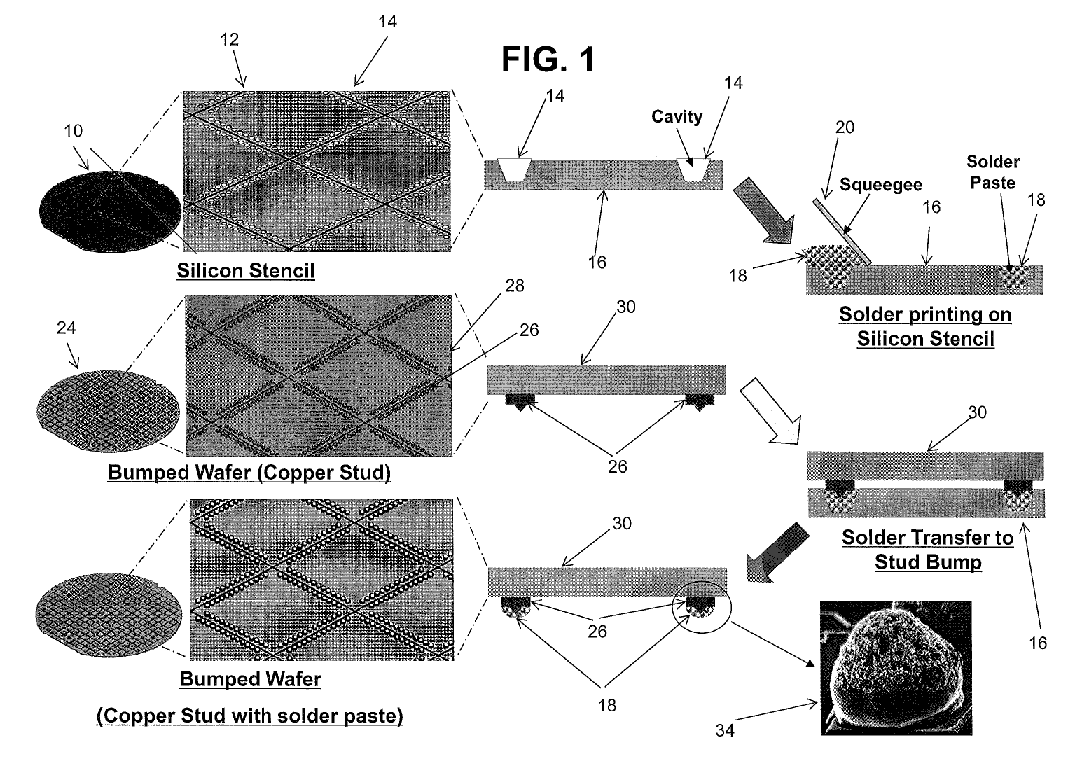

FIG. 1 shows a stencil 10 in the shape of a wafer, although this technique could be practiced at the die level also. As shown in the magnified portion 12 of the wafer 10, a plurality of cavities 14 have been defined therein and in this case they are defined around the periphery of the defined region that corresponds to an individual die on the wafer that is to have solder added thereto. The further magnified portion 16 shows two of the cavities 14 in a cross-sectional view. Next, solder paste 18 is printed into the cavities 14 on the stencil 16. After that, a wiper or squeegee 20 may be dragged across the top of the stencil 16 to remove excess solder paste that is outside of the cavities 14. The stencil 10 is then ready for transfer of the solder paste 18 as will be described below.

In parallel, a wafer 24 of individual dies has a plurality of electrical contacts that have had stud bumps 26 of a suitable conductive material (e.g., copper) affixed thereto. FIG. 1 shows the wafer 24, a magnified portion 28 showing the stud bumps 26 around the periphery of each die and a further magnified portion 30 showing two of the stud bumps 26. The wafer 24 is now ready for transfer of the solder paste 18.

Next, the two wafers 10 and 24 are brought into an opposing and adjacent relationship with each other, and they are moved into a position where each of the stud bumps 26 is inserted into one of the cavities 14 and into contact with the solder paste 18. The wafers are then separated and each of the stud bumps 26 will have a layer of solder paste 18 thereon as shown, and particularly as shown in significantly magnified form 34.

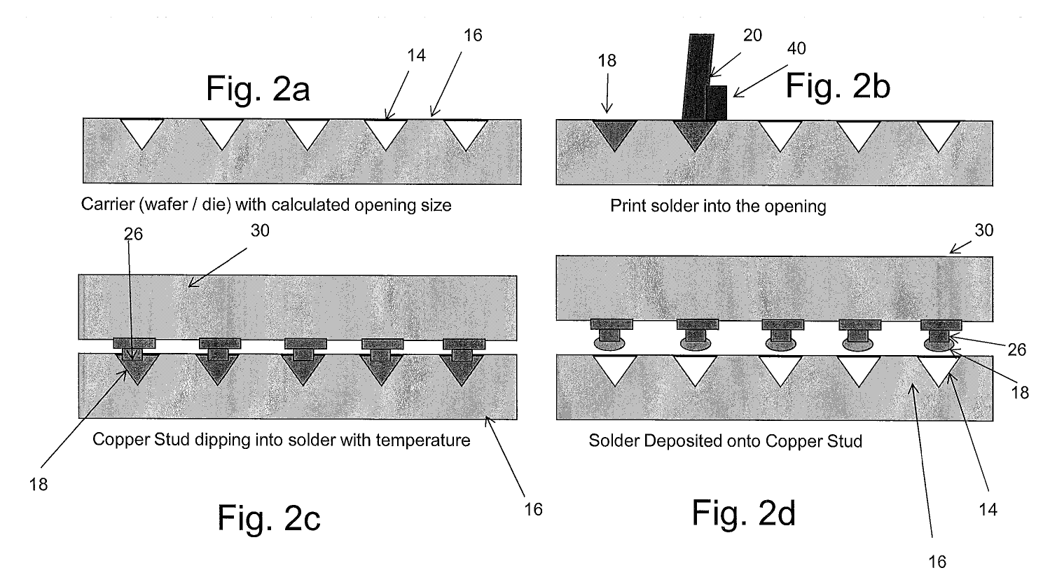

FIGS. 2a-2d show further details of this process. As shown in FIG. 2a, the stencil or carrier 16 has a plurality of cavities 14 defined therein. FIG. 2b shows the process of printing solder paste 18 from a print head 40 and the squeegee 20 that is used to remove excess solder paste 18. FIG. 2c shows the wafer 30 with the stud bumps 26 in proximity to the wafer 16 so that the stud bumps 26 extend into the cavities 14 and come into contact with the solder paste 18. As is noted, there may be some general or localized heating to heat the solder paste 18 and stud bumps 26 and assist with the transfer of the solder paste 18 to the stud bumps 26. FIG. 2d shows the wafer 30 moved away from the wafer 16 so that the stud bumps 26 are removed from the cavities 14 with the solder paste 18 now attached to the stud bumps 26.

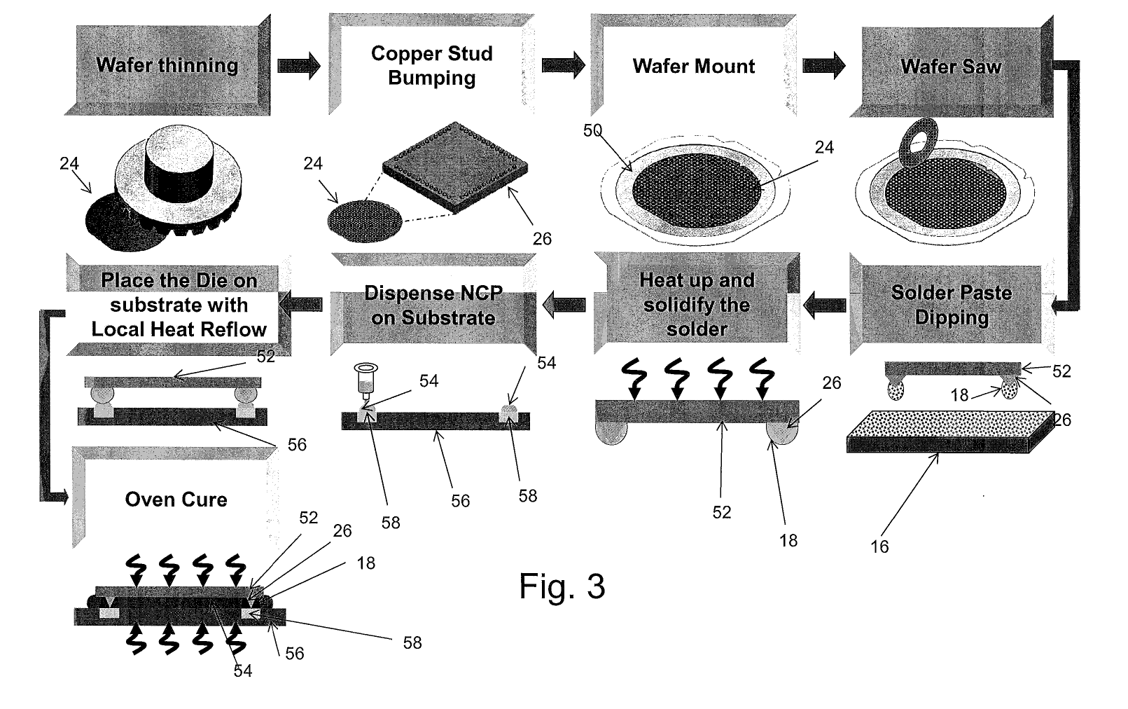

FIG. 3 provides details about one variant of the process. As a first step, the wafer 24 of individual dies is thinned in order to planarize the wafer 24. Next, the copper stud bumps 26 are added to the electrical contacts on the wafer 24. Next, the wafer 24 may be mounted on dicing tape 50 or the like. Next, the wafer 24 is sawed into individual die 52. After this, each die 52 can be picked up from the dicing tape 50 and moved into position relative to the stencil to receive the solder paste 18 on each of the stud bumps 26. Next, the solder paste 18 may be heated up to solidify the solder. Next, a non-conductive paste (NCP) 54 is dispensed onto a substrate 56 (e.g., a PCB or flexible circuit board or the like or other electronic component) to which the die 52 will be attached. Although the illustration of FIG. 3 appears to show the NCP 54 being dispensed only on top of electrical contacts 58 on the substrate 56, the NCP 54 may actually be dispensed in a pattern across the portion of the substrate 56 corresponding to the die 52. The die 52 is then placed on the substrate 56 with the stud bumps 26 aligned with the electrical contacts 58 and localized heating is used to reflow the solder. The entire assembly can then be placed into an oven to cure the NCP 54 which has now distributed itself in a layer underneath and supporting the die 52, due to the pressure of the die 52 being placed in proximity to the substrate 56.

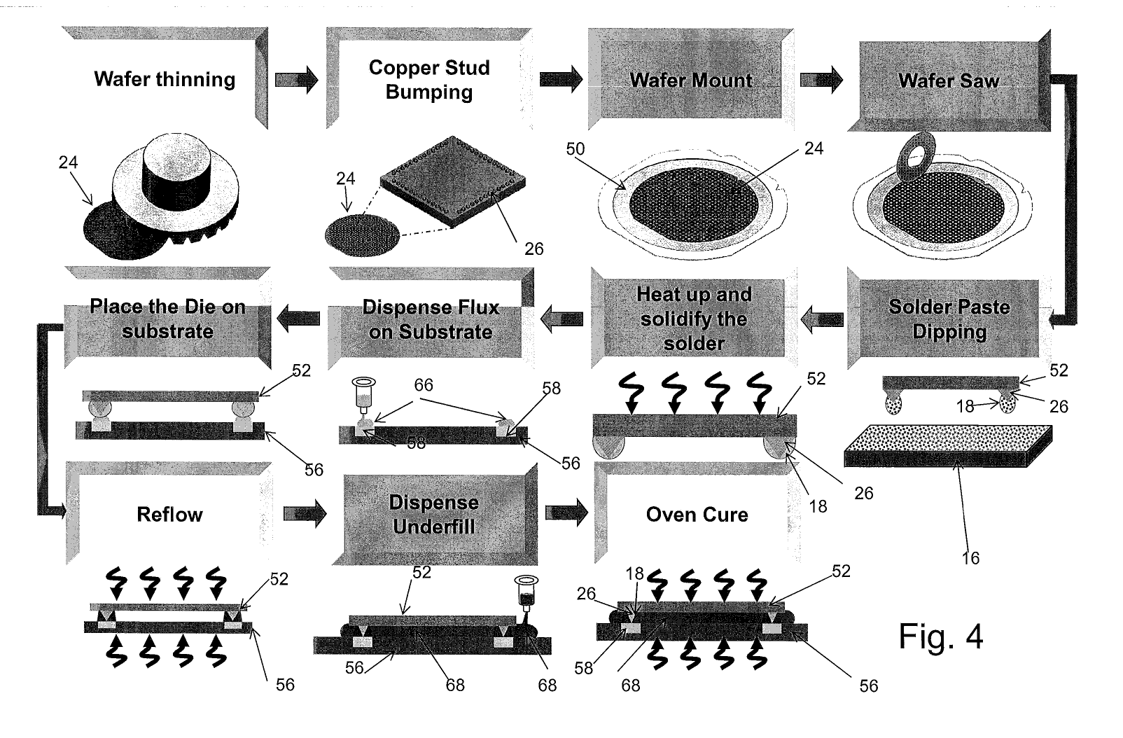

FIG. 4 provides details about another variant of the process. As a first step, the wafer 24 of individual dies is thinned in order to planarize the wafer 24. Next, the copper stud bumps 26 are added to the electrical contacts on the wafer 24. Next, the wafer 24 may be mounted on dicing tape 50 or the like. Next, the wafer 24 is sawed into individual die 52. After this, each die 52 can be picked up from the dicing tape 50 and moved into position relative to the stencil to receive the solder paste 18 on each of the stud bumps 26. Next, the solder paste 18 may be heated up to solidify the solder. Next, flux 66 is dispensed onto the substrate 56 (e.g., a PCB or flexible circuit board or the like or other electronic component) to which the die 52 will be attached. Although the illustration of FIG. 4 appears to show the flux 66 being dispensed only on top of the electrical contacts 58 on the substrate 56, the flux 66 may actually be dispensed in a pattern across the portion of the substrate 56 corresponding to the die 52. The die 52 is then placed on the substrate 56 with the stud bumps 26 aligned with the electrical contacts 58 and the solder is reflowed. Next, underfill 68 is dispensed between the die 52 and the substrate 56 and then the entire assembly can be placed into an oven to cure the underfill 66.

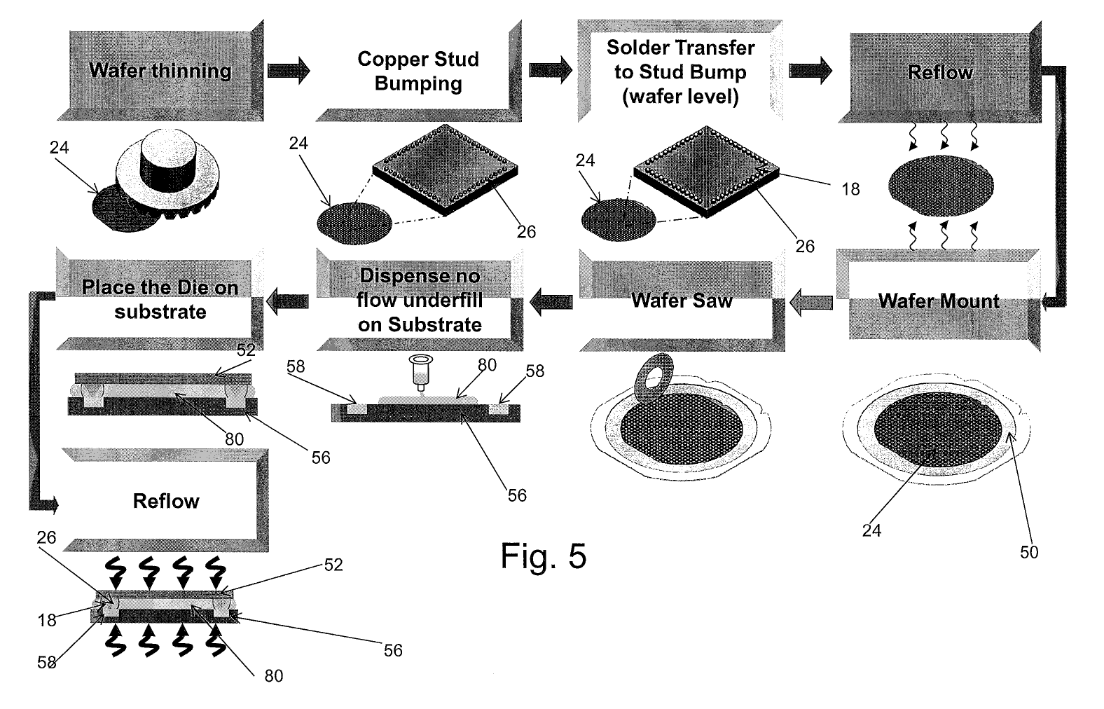

FIG. 5 provides details about another variant of the process. As a first step, the wafer 24 of individual die is thinned in order to planarize the wafer 24. Next, the copper stud bumps 26 are added to the electrical contacts on the wafer 24. Next, at the wafer level, a stencil with cavities containing solder paste is used to transfer solder paste 18 to the stud bumps 26. The solder is then reflowed. Next, the wafer 24 may be mounted on dicing tape 50 or the like. The wafer 24 is then sawed into individual die 52. After this, no-flow underfill (underfill plus flux) 80 may be dispensed onto the substrate 56 to which the die 52 will be attached. The die 52 is then placed on the substrate 56 with the stud bumps 26 aligned with the electrical contacts 58 and the solder is then reflowed.

The disclosed manufacturing technique provides several advantages over the prior art. As can be seen, these approaches provide simple and low cost solutions for applying solder without expensive processes like sputtering and lithography. It is also easy to control the solder volume used based on the volume of each cavity. It is easy to switch between different solder materials. Optionally, stud bump coining (producing a more regular surface on the stud bump) can be performed. The stencil or carrier for the solder paste may be composed of silicon and the cavities produced by wet etching. The stencil can be used again and again. Additional solder volume can be added to effectively increase the bump height. Lastly, this technique reduces issues with planarity of the substrate (e.g., PCB, flex, etc.).

While the embodiments of the invention have been illustrated and described in detail in the drawings and foregoing description, such illustration and description are to be considered as examples and not restrictive in character. For example, certain embodiments described hereinabove may be combinable with other described embodiments and/or arranged in other ways (e.g., process elements may be performed in other sequences). Accordingly, it should be understood that only example embodiments and variants thereof have been shown and described.

We claim:

1. A method for applying solder to stud bumps on a die, comprising:
providing a die with a plurality of stud bumps, each stud bump affixed to a corresponding metal pad on the die;
providing a stencil with a plurality of cavities corresponding to the relative positions of the stud bumps on the die;
placing solder paste into the cavities of the stencil;
dipping the stud bumps into the cavities of the stencil so as to cause the solder paste to come into contact with the stud bumps; and
removing the stud bumps from the cavities so that the solder paste is affixed to the stud bumps.

2. A method as defined in claim 1, further including wiping away excess solder paste from the stencil in the areas outside of the cavities.

3. A method as defined in claim 1, wherein the die has been created from a wafer of a plurality of die.

4. A method as defined in claim 1, wherein a plurality of the die are connected together as part of a wafer and the stencil has cavities for all of the stud bumps on all of the die on the wafer.

5. A method as defined in claim 1, wherein the solder paste has been heated to elevate the temperature thereof to facilitate the solder in the solder paste affixing to the stud bumps.

6. A method as defined in claim 5, further including cooling down the solder after it has been affixed to the stud bumps and prior to removing the stud bumps from the cavities.

7. A method as defined in claim 1, wherein the stud bumps on the die include copper.

8. A method as defined in claim 1, wherein the solder is placed into the cavities by printing.

9. A method as defined in claim 1, further including providing a substrate with metal contacts corresponding to the stud bumps on the die; and
affixing the stud bumps to the metal contacts on the substrate with the solder.

10. A method as defined in claim 9, further including reflowing the solder.

11. A method as defined in claim 9, further including adding an adhesive material between the die and the substrate to further affix the die and substrate together.

12. A method as defined in claim 11, wherein the adhesive material includes underfill.

13. A method as defined in claim 12, wherein the adhesive material is dispensed after the die has been affixed to the substrate with the solder.

14. A method as defined in claim 12, wherein the adhesive material is dispensed before the die has been affixed to the substrate with the solder.

15. A method as defined in claim 14, wherein the adhesive material also includes flux.

16. A method as defined in claim 12, wherein the underfill is dispensed in a pattern across the substrate.

17. A method as defined in claim 11, wherein the adhesive material includes non-conductive paste (NCP).

18. A method as defined in claim 17, wherein the NCP is dispensed in a pattern across the substrate.

19. A method as defined in claim 11, further including curing the adhesive.

20. A method as defined in claim 1, wherein all of the stud bumps are dipped into the cavities simultaneously.
